(19) United States
(12) Patent Application Publication
(10) Pub. No.: US 2011/0188674 A1
(43) Pub. Date: Aug. 4, 2011

(54) TELEVISION SYSTEM AND CHANNEL SELECTING METHOD AND VOLUME CONTROL METHOD

(75) Inventor: LUNG DAI, Tu-Cheng (TW)

(73) Assignee: HON HAI PRECISION INDUSTRY CO., LTD., Tu-Cheng (TW)

(21) Appl. No.: 12/848,885

(22) Filed: Aug. 2, 2010

(30) Foreign Application Priority Data
Feb. 1, 2010 (TW) 99102772

(51) Int. Cl. H04N 5/44; H03G 3/00

(52) U.S. Cl. 381/105; 348/734; 348/E05.096

(57) ABSTRACT

A television system includes a remote control and a television. The remote control includes a sensor and a transmitting unit. The sensor generates a detecting signal according to a user's operation. When the user' operations are different, the detecting signals are different. The transmitting unit transmits the detecting signal. The television includes a receiving unit, a determining unit, and a channel selecting unit. The receiving unit receives the detecting signal. The determining unit determines whether the detecting signal is a first channel signal or a second channel signal. The determining unit generates a first control signal when the detecting signal is the first channel signal, and generates a second control signal when the detecting signal is the second channel signal. The channel selecting unit selects the last channel in response to the first control signal, and selects the next channel in response to the second control signal.

### BACKGROUND

1. Technical Field

The present disclosure relates to a remote control; and particularly to a television system using the remoter control, and a channel selecting method and a volume control method thereof.

2. Description of Related Art

A remote control used with a television often includes channel selecting keys and volume control keys. The keys are often arranged above resilient members, and the restoring forces of the resilient members may be weakened after repeatedly pressing the keys, thus the reliability of the remote control decreases with use.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout two views.

FIG. 1 is a block diagram of a television system in accordance with an exemplary embodiment.

FIG. 2 is a flowchart of a remote control method in accordance with an exemplary embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

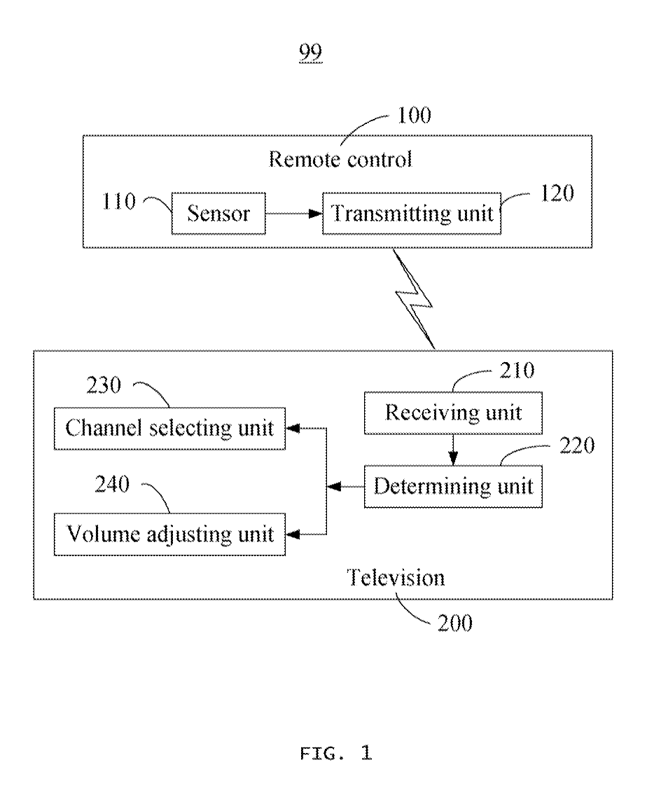

Referring to FIG. 1, a television system 99 includes a television 200, and a remote control 100 corresponding to the television 200. The remote control 100 is used for controlling the television 200 to select a channel and adjust the volume.

The remote control 100 includes a sensor 110 and a transmitting unit 120. The sensor 110 is used for generating a detecting signal according to a user's operation. When the user's operations are different, the detecting signals are different.

In the embodiment, when a user rotates the remote control 100 upward exceeding a predetermined angle, the sensor 110 generates a first channel signal. When a user rotates the remote control 100 downward exceeding the predetermined angle, the sensor 110 generates a second channel signal. When a user rotates the remote control 100 left exceeding the predetermined angle, the sensor 110 generates a first volume signal. When a user rotates the remote control 100 right exceeding the predetermined angle, the sensor 110 generates a second volume signal. The predetermined angle may be about 30 degrees. It is noteworthy that the rotation action can be replaced with another operation.

The transmitting unit 120 is used for transmitting the detecting signal generated by the sensor 110 to the television 200. The transmitting unit 120 may be an infrared emitter.

The television 200 includes a receiving unit 210, a determining unit 220, a channel selecting unit 230, and a volume adjusting unit 240. The receiving unit 210 is used for receiving the detecting signal transmitted by the transmitting unit 120 of the remote control 100. The receiving unit 210 may be an infrared receiver.

The determining unit 220 is used for determining whether the detecting signal is the first channel signal, the second channel signal, the first volume signal, or the second volume signal, and generating a control signal according to the determined result.

When it is determined that the detecting signal is the first channel signal, the determining unit 220 generates a first control signal, and transmits the first control signal to the channel selecting unit 230 such that the channel selecting unit 230 selects the last channel in response to the first control signal.

When it is determined that the detecting signal is the second channel signal, the determining unit 220 generates a second control signal, and transmits the second control signal to the channel selecting unit 230 such that the channel selecting unit 230 selects the next channel in response to the second control signal.

When the detecting signal is the first volume signal, the determining unit 220 generates a third control signal, and transmits a third control signal to the volume adjusting unit 240 such that the volume adjusting unit 240 turns up the volume on the television 200 in response to the third control signal.

When the detecting signal is the second volume signal, the determining unit 220 generates a fourth control signal, and transmits the fourth control signal to the volume adjusting unit 240 such that the volume adjusting unit 240 turns down the volume on the television 200 in response to the fourth control signal.

Using the above described television system 99, a user can rotate the remote control 100 to select the channel and adjust the volume, and the sensor 110 is still functional after repetitious use. Therefore, the reliability of the television system 99 is improved.

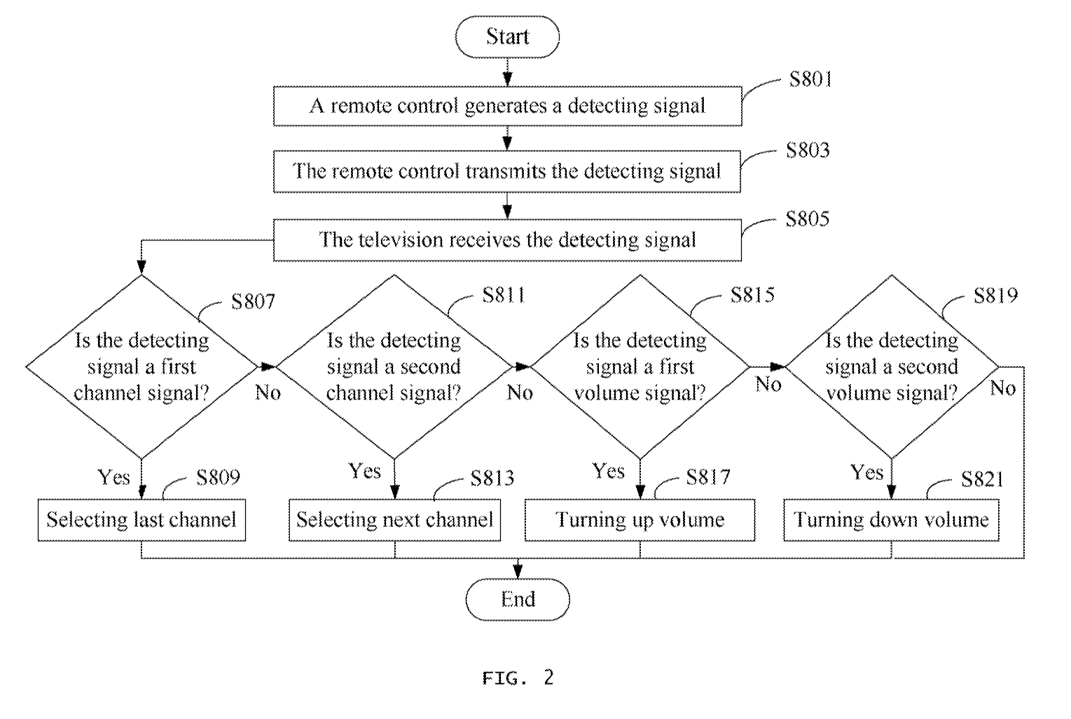

Referring to FIG. 2, a remote control method is used for controlling a television to select a channel and adjust the volume with a remote control. The remote control method includes the following steps.

In step S801, the remote control generates a detecting signal according to a user's operation. When the user's operations are different, the detecting signals are different. In the embodiment, when the user rotates the remote control upward exceeding a predetermined angle, the sensor generates a first channel signal. When the user rotates the remote control downward exceeding the predetermined angle, the sensor generates a second channel signal. When the user sways the remote control left exceeding the predetermined angle, the sensor generates a first volume signal. When the user rotates the remote control right exceeding the predetermined angle, the sensor generates a second volume signal. The predetermined angle may be about 30 degrees. It is noteworthy that the rotating action can be replaced with another operation.

In step S803, the remote control transmits the detecting signal. The remote control may transmit the detecting signal using infrared rays.

In step S805, the television receives the detecting signal. The television may receive the detecting signal using infrared detecting sensors.

In step S807, determining whether the detecting signal is the first channel signal. If it is determined that the detecting signal is the first channel signal, step S809 is implemented. If it is determined that the detecting signal is not the first channel signal, step S811 is implemented.

In step S809, the television selects the last channel to play.

In step S811, determining whether the detecting signal is the second channel signal. If it is determined that the detecting signal is the second channel signal, step S813 is implemented. If it is determined that the detecting signal is not the second channel signal, step S815 is implemented.

In step S813, the television selects the next channel to play.

In step S815, determining whether the detecting signal is the first volume signal. If it is determined that the detecting signal is the first volume signal, step S817 is implemented. If it is determined that the detecting signal is not the first volume signal, step S819 is implemented.

In step S817, the television turns up the volume.

In step S819, determining whether the detecting signal is the second volume signal. If it is determined that the detecting signal is the second volume signal, step S821 is implemented. If it is determined that the detecting signal is not the second volume signal, the procedure is ended.

In step S821, the television turns down the volume.

It is noteworthy that an order of the steps S807, S811, S815, and S819 is changeable.

It is to be understood, even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. A television system, comprising:
a remote control comprising:
a sensor adapted to generate a detecting signal according to a user's operation, wherein when the user' operations are different, the detecting signals are different; and
a transmitting unit adapted to transmit the detecting signal; and
a television comprising:
a receiving unit adapted to receive the detecting signal transmitted by the transmitting unit of the remote control;
a determining unit adapted to determine whether the detecting signal is a first channel signal or a second channel signal, the determining unit adapted to generate a first control signal when it is determined the detecting signal is the first channel signal, and generate a second control signal when it is determined the detecting signal is the second channel signal; and
a channel selecting unit adapted to select the last channel in response to the first control signal, and select the next channel in response to the second control signal.

2. The television system according to claim 1, wherein when a user rotates the remote control upward exceeding a predetermined angle, the sensor generates the first channel signal, and when a user rotates the remote control downward exceeding the predetermined angle, the sensor generates the second channel signal.

3. The television system according to claim 1, further comprising a volume adjusting unit, the determining unit further adapted to determine whether the detecting signal is a first volume signal or a second volume signal, the determining unit adapted to generate a third control signal when it is determined the detecting signal is the first volume signal, and generate a fourth control signal when it is determined the detecting signal is the second volume signal; the volume adjusting unit adapted to turn up the volume of the television in response to the third control signal, and adapted to turn down the volume of the television in response to the third control signal.

4. The television system according to claim 3, wherein when a user rotates the remote control left exceeding a predetermined angle, the sensor generates the first volume signal; and when a user rotates the remote control right exceeding the predetermined angle, the sensor generates the second volume signal.

5. A channel selecting method for controlling a television to select a channel via a remote control, comprising:
the television receives a detecting signal transmitted by the remote control, the remote control adapted to generate the detecting signal according to a user's operation, wherein when the user's operations are different, the detecting signals are different;
determining whether the detecting signal is a first channel signal; and
if it is determined the detecting signal is the first channel signal, the television selecting the last channel to play.

6. The channel selecting method according to claim 5, wherein when a user rotates the remote control upward exceeding a predetermined angle, the remote control generates the first channel signal.

7. The channel selecting method according to claim 5, further comprising:
determining whether the detecting signal is a second channel signal; and
if it is determined the detecting signal is the second channel signal, the television selecting the next channel to play.

8. The channel selecting method according to claim 7, wherein when a user rotates the remote control downward exceeding the predetermined angle, the remote control generates the second channel signal.

9. A volume control method for controlling a television to adjust the volume via a remote control, comprising:
the television receives a detecting signal transmitted by the remote control, the remote control adapted to generate the detecting signal according to a user's operation, wherein when the user's operations are different, the detecting signals are different;
determining whether the detecting signal is a first volume signal; and
if it is determined the detecting signal is the first volume signal, the television turning up the volume.

10. The volume control method according to claim 9, wherein when a user rotates the remote control left exceeding a predetermined angle, the remote control generates the first volume signal.

11. The volume control method according to claim 9, further comprising:
determining whether the detecting signal is a second volume signal; and
if it is determined the detecting signal is the second volume signal, the television turning down the volume.

12. The volume control method according to claim 11, wherein when a user rotates the remote control right exceeding the predetermined angle, the remote control generates the second volume signal.
